(19) United States
(12) Patent Application Publication
(10) Pub. No.: US 2014/0125350 A1
(43) Pub. Date: May 8, 2014

(54) CONNECTOR AND ELECTRICAL LEAKAGE DETECTION DEVICE

(71) Applicant: FUJITSU LIMITED, Kawasaki-shi (JP)

(72) Inventor: Yasuhiro SENBA, Kawasaki (JP)

(73) Assignee: FUJITSU LIMITED, Kawasaki-shi (JP)

(21) Appl. No.: 14/049,771

(22) Filed: Oct. 9, 2013

(30) Foreign Application Priority Data
Nov. 5, 2012 (JP) 2012-243796

(51) Int. Cl. G01R 31/02

(52) U.S. Cl. CPC G01R 31/025
USPC 324/509; 439/517

(57) ABSTRACT

A connector includes a first terminal to which a power supply is connected, the power supply being a direct current power supply, a second terminal to which a signal ground of the direct current power supply is connected, and a third terminal connected to a frame ground, the third terminal being arranged at a location between the first terminal and the second terminal.

### CROSS-REFERENCE TO RELATED APPLICATION

This application is based upon and claims the benefit of priority of the prior Japanese Patent Application No. 2012-243796, filed on Nov. 5, 2012, the entire contents of which are incorporated herein by reference.

### FIELD

The embodiment discussed herein is related to a connector and a device for detecting an electrical leakage.

### BACKGROUND

In devices that use direct current (DC) power supplies, a high current would flow if a short circuit occurs between a power supply voltage and a ground voltage. For example, if dew condensation occurs in a power supply connector portion, a leakage current flows between the terminals. The heat generated by the current causes a substrate portion to be gradually carbonized. As a result, the leakage current is increasing. In order to inhibit such a short circuit due to a leakage current, it is conceivable to take a measure such as extending the distance between pins in the power supply connection portion.

Typically, measures such as extending the distance between pins in the power supply connection portion and extending intervals between power supply patterns in the substrate are taken in order to inhibit a short circuit due to a leakage current. A device for which such a measure has been taken, however, has problems in that the size is enlarged and the device price becomes high. If a large amount of short-circuit current (for example, several tens of amperes) flows, a breaker operates to interrupt the power supply. However, only a relatively small amount of current (for example, 100 mA) flows during a short circuit due to a leakage current, and therefore there is a risk that the electrical leakage gradually increases while the breaker remains off.

In a communication device, a large number of circuit boards (circuit cards) are mounted to a back wiring board within a shelf, and a DC power supply is supplied through the back wiring board. It is not preferable that a short circuit due to a leakage current as mentioned above occurs in a terminal portion of the back wiring board. A large number of circuit boards are expected to be mounted to the back wiring board, and therefore there are sometimes cases where it is difficult to extend the distance between pins of the power supply connector, and where an electrical leakage is not completely inhibited only by extending the distance between pins depending on the mounting conditions and the like.

Japanese Laid-open Patent Publication No. 10-223286 and Japanese Laid-open Patent Publication No. 2009-264989 disclose examples of the related art.

In view of the above, an electrical leakage detection device that detects a short circuit due to a leakage of a DC power supply in a wiring board, and a connector suitable for detecting a short circuit due to an electrical leakage are desired.

### SUMMARY

According to an aspect of the invention, a connector includes a first terminal to which a power supply is connected, the power supply being a direct current power supply, a second terminal to which a signal ground of the direct current power supply is connected, and a third terminal connected to a frame ground, the third terminal being arranged at a location between the first terminal and the second terminal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example configuration of an electronic device including an electrical leakage detection device;

FIG. 2 illustrates an example configuration of a conventional connector provided on a substrate of a back wiring board;

FIG. 3 illustrates an example configuration of a connector of this embodiment provided on the substrate of the back wiring board;

FIG. 4 illustrates an example configuration of a pin inserted into the substrate of the back wiring board and a pin inserted into a substrate on a circuit board side;

FIG. 5 illustrates an example configuration of a connector provided on the substrate on the circuit board side;

FIG. 6 illustrates an example configuration of an electrical leakage detection circuit; and

FIG. 7 illustrates an example of a plurality of circuit boards mounted to the back wiring board.

### DESCRIPTION OF EMBODIMENT

Hereinafter, an embodiment of the present disclosure will be described in detail with reference to the accompanying drawings. In each drawing, the same or corresponding elements are denoted by the same or corresponding numerals, and the description is omitted as appropriate.

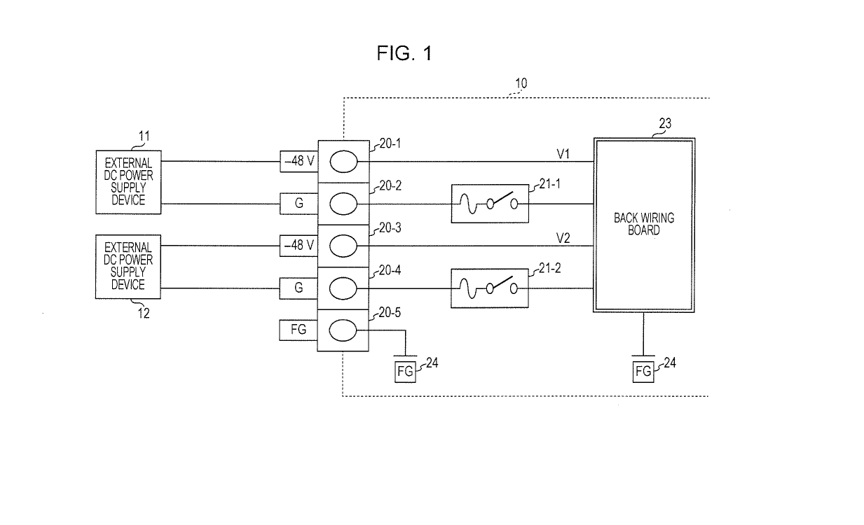

FIG. 1 illustrates an example configuration of an electronic device 10 including an electrical leakage detection device. The electronic device 10 includes receiving terminals 20-1 to 20-5, breakers 21-1 and 21-2, a back wiring board 23, and a frame ground 24. The back wiring board 23 is provided within a shelf, and a plurality of circuit boards (board cards) are able to be mounted to the back wiring board 23, as described later. For example, mounting a communication-related circuit board in the back wiring board 23 enables the electronic device 10 to be used as a communication device. Note that an electrical leakage detection device described below may be applied to any wiring board that is capable of receiving a board card, and it is unnecessary that the electrical leakage detection device is applied to the back wiring board 23 arranged on the back surface within the shelf of a communication device or the like.

The power supply and the ground of the external DC power supply device 11 are supplied to the receiving terminals 20-1 and 20-2, and the power supply and the ground of the external DC power supply device 12 are supplied to the receiving terminals 20-3 and 20-4. The two power supplies of the external DC power supply devices 11 and 12 provide a redundant configuration in which if one power supply has a trouble, the other power supply enables the electronic device 10 to operate.

The power supply voltage supplied by the external DC power supply device 11 is at a potential of −48 V relative to the ground supplied by the external DC power supply device 11. Likewise, the power supply voltage supplied by the external DC power supply device 12 is at a potential of −48 V relative to the ground supplied by the external DC power supply device 12. The receiving terminal 20-5 is connected to the frame ground 24 directly connected to the frame of the electronic device 10. In the below description, the ground of each of the external DC power supply devices 11 and 12 will be referred to as a “signal ground” in order to distinguish it from the frame ground 24.

The signal ground is on one voltage side that is either the plus side or minus side of the voltage of a power supply supplied to an electronic circuit or an electrical circuit, and provides a potential that serves as a reference for the operation of the electronic circuit or the electrical circuit. The frame ground is provided in order to make the frame of an electronic circuit or an electrical circuit to be at the same potential as the earth for the safety purpose such as protection against an electric shock. The frame ground is connected to the earth through a ground line and provides a stable potential.

The power supply voltage of the external DC power supply device 11 is supplied through the breaker 21-1 to the back wiring board 23. The power supply voltage of the external DC power supply device 12 is supplied through the breaker 21-2 to the back wiring board 23. If an overcurrent flows through the power supply path of the external DC power supply device 11, the interruption function of the breaker 21-1 operates to interrupt the power supply. Likewise, if an overcurrent flows through the power supply path of the external DC power supply device 12, the interruption function of the breaker 21-2 operates to interrupt the power supply.

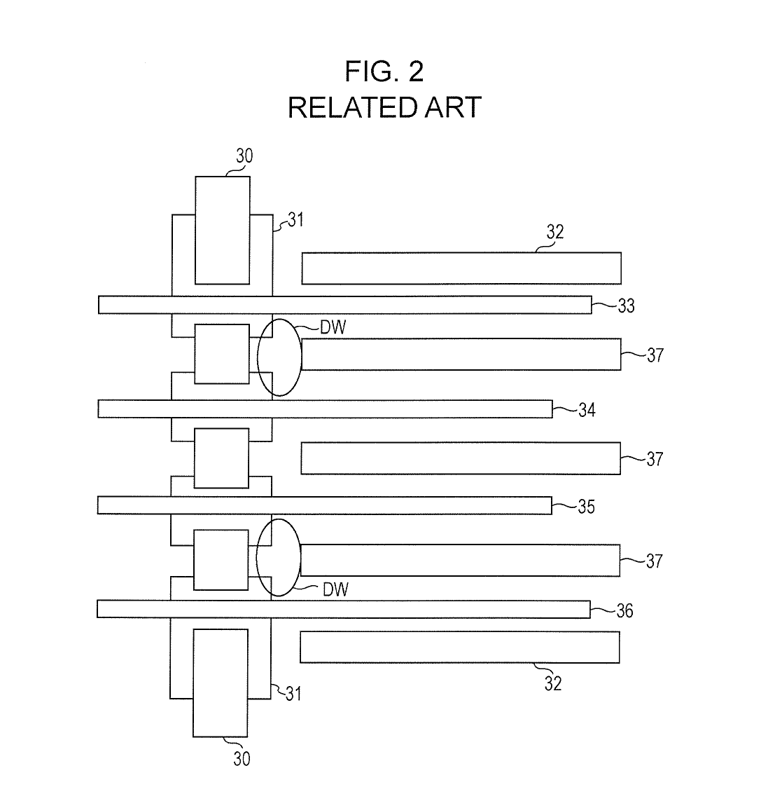

FIG. 2 illustrates an example configuration of a conventional connector provided on the substrate of the back wiring board 23. On the back wiring board 23, one connector illustrated in FIG. 2 is provided at one mounting location at which one circuit board is to be mounted. The connector of FIG. 2 includes a connector case 32, a frame ground pin 33, a first power supply pin 34, a second power supply pin 35, a signal ground pin 36, and a connector partition 37. The connector case 32 is a case made of a resin, for example, for protecting the pins from the outside. The pins 33 to 36 are provided inside the connector case 32, and are isolated from each other by the connector partition 37. As described later, each pin is inserted into a hole formed in the substrate 30 of the back wiring board 23 in such a manner that the substrate 30 is pierced with the pin, so that the pin is fixed. More particularly, the hole formed in the substrate 30 is provided with a copper foil 31, and each pin is piercingly inserted into the copper foil 31. Through the copper foil 31, the power supply of the external DC power supply device 11 is connected to the first power supply pin 34, and the power supply of the external DC power supply device 12 is connected to the second power supply pin 35. Likewise, the signal ground of each of the external DC power supply devices 11 and 12 is connected to the signal ground pin 36.

In the configuration of the conventional connector illustrated in FIG. 2, the frame ground pin 33 and the first power supply pin 34 are adjacent to each other, and the second power supply pin 35 and the signal ground pin 36 are adjacent to each other. Accordingly, if dew condensation DW occurs, a leakage current flows between these adjacent pins (terminals). In the case of a leakage current having a relatively small current amount, there is a risk that the heat of the leakage current gradually promotes carbonization of the substrate, and the leakage current is increasing while the breaker remains off, resulting in an increase in heat generation.

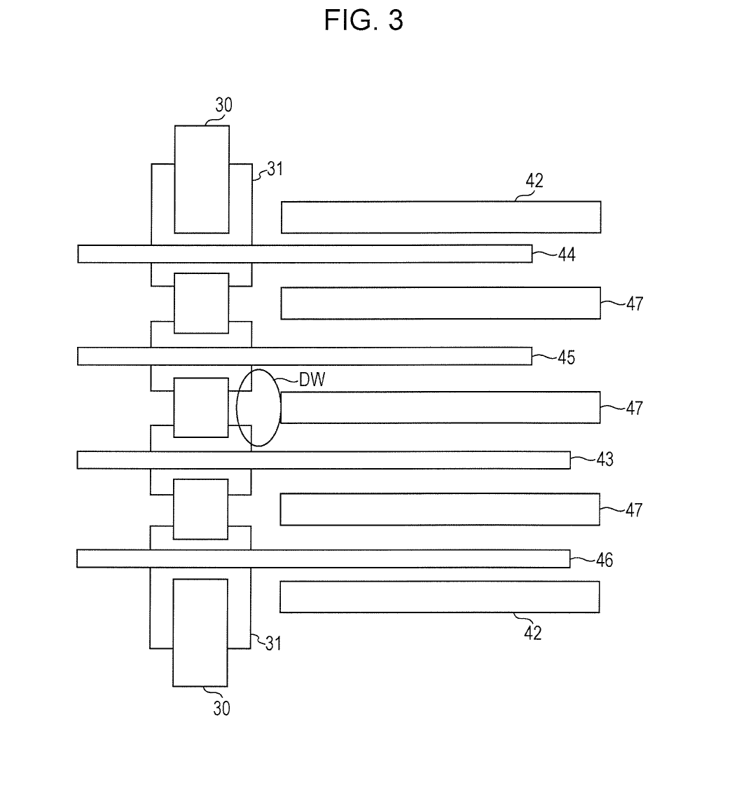

FIG. 3 illustrates an example configuration of a connector of this embodiment provided on the substrate of back wiring board 23. On the back wiring board 23, one connector illustrated in FIG. 3 is provided at one mounting location at which one circuit board is to be mounted. The connector of FIG. 3 includes a connector case 42, a frame ground pin 43, a first power supply pin 44, a second power supply pin 45, a signal ground pin 46, and a connector partition 47. These pins 43 to 46 (terminals) are provided at the mounting location of each of a plurality of boards mounted to the back wiring board 23.

The connector case 42 is a case made of a resin, for example, for protecting pins (terminals) from the outside. The pins 43 to 46 are provided inside the connector case 42, and are isolated from each other by the connector partition 47. As described later, each pin is inserted into a hole formed in the substrate 30 of the back wiring board 23 in such a manner that the substrate 30 is pierced with the pin, so that the pin is fixed. More particularly, the hole formed in the substrate 30 is provided with the copper foil 31, and each pin is piercingly inserted into the copper foil 31. Through the copper foil 31, the power supply of the external DC power supply device 11 is connected to the first power supply pin 44, and the power supply of the external DC power supply device 12 is connected to the second power supply pin 45. Likewise, the signal ground of each of the external DC power supply devices 11 and 12 is connected to the signal ground pin 46.

In the configuration of the connector of this embodiment illustrated in FIG. 3, the frame ground pin 43 is arranged at a location between the second power supply pin 45 and the signal ground pin 46. The frame ground pin 43 serves as a function for protecting the signal ground pin 46, which makes it difficult to cause a situation where the second power supply pin 45 and the signal ground pin 46 are directly combined because of dew condensation. That is, even if the dew condensation DW occurs and the second power supply pin 45 and the frame ground pin 43 are electrically connected, the second power supply pin 45 and the signal ground pin 46 are less likely to enter a state where the second power supply pin 45 and the signal ground pin 46 are directly combined with the dew condensation. Accordingly, if a leakage current flows between the second power supply pin 45 and the frame ground pin 43 through dew condensation, a situation where a leakage current directly flows between the second power supply pin 45 and the signal ground pin 46 through dew condensation is less likely to occur. Additionally, since a leakage current flows between the second power supply pin 45 and the frame ground pin 43, the relative potential of the frame ground pin 43 with respect to the signal ground pin 46 varies. Accordingly, providing a detection circuit for detecting a potential difference between the potential of the signal ground and the potential of the frame ground enables the presence of absence of a leakage current to be detected.

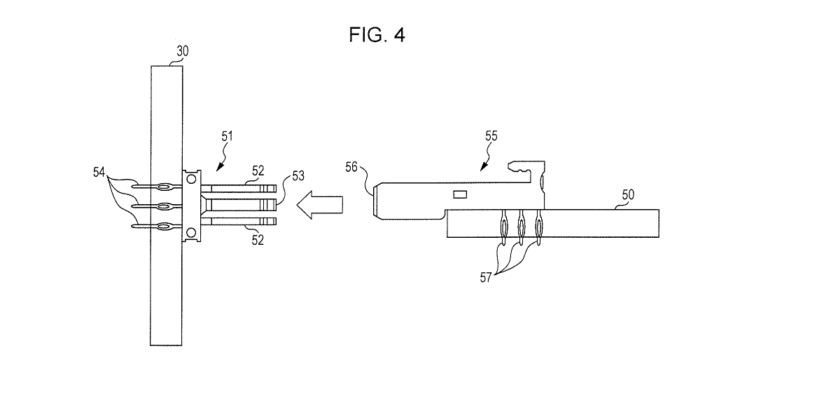

FIG. 4 illustrates an example configuration of a pin inserted into the substrate of the back wiring board 23 and a pin inserted into a substrate on a circuit board side. A pin 51 is mounted to the substrate 30 of the back wiring board 23. Each of the pins 43 to 46 illustrated in FIG. 3 may be a pin having the same shape as the pin 51. FIG. 4 is a top view of the pin 51, and each pin illustrated in FIG. 3 corresponds to the pin 51 viewed from the side. The pin 51 has three end bar portions 54, and the end bar portions 54 are stuck into the substrate 30 until the roots of the end bar portions 54 reach the substrate 30. The pin 51 has mating portions 52 and 53 at the end on a side opposite to the end bar portions 54.

A pin 55 is mounted to the substrate 50 of a circuit board mounted to the back wiring board 23. The pin 55 has three side bar portions 57, and the side bar portions 57 are stuck into the substrate 50 until the roots of the side bar portions 57 reach the substrate 50. An end flat portion 56 of the pin 55 is inserted in such a manner as to be sandwiched between the mating portion 52 and the mating portion 53 of the pin 51, so that the pin 55 and the pin 51 mate with each other to be electrically connected.

More particularly, when the pin 51 whose top view is illustrated in FIG. 4 is viewed from the side, the position of the mating portion 52 is vertically displaced from the position of the mating portion 53, and the end flat portion 56 of the pin 55 is trapped in a clearance generated between the mating portion 52 and the mating portion 53 by the vertical position displacement. As described above, each of the pins 43 to 46 illustrated in FIG. 3 corresponds to the pin 51 viewed from the side. Strictly speaking, each of the pins 43 to 46 illustrated in FIG. 3 has a mating portion that is vertically displaced and has a clearance. In FIG. 3, the vertical displacement and the clearance of mating portions as such are omitted, and the pins are illustrated in simplified shapes.

As illustrated as the four pins 43 to 46 in FIG. 3, four pins 51 are provided for one connector on the side of the back wiring board 23. Four pins 55 are also provided on the substrate 50 on the circuit board side, and these pins are covered with a connector case made of a resin, for example, thereby forming a connector on the substrate 50. By mating of the pins and mating of the connector cases between the back wiring board 23 and the circuit board, the circuit board is mounted and fixed to the back wiring board 23.

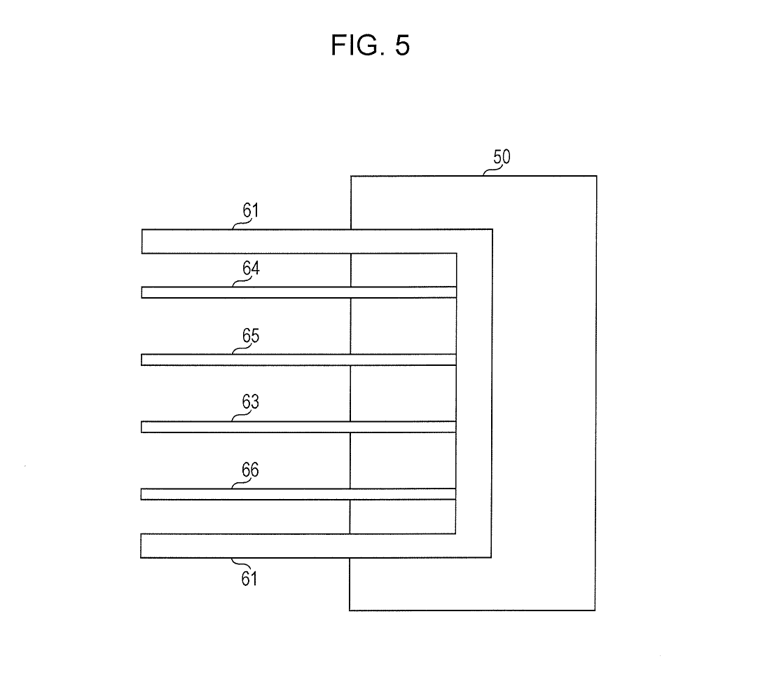

FIG. 5 illustrates an example configuration of a connector provided on the substrate on the circuit board side. The connector provided on the substrate 50 includes a connector case 61 and four pins 63 to 66. Each of the four pins 63 to 66 may be a pin having the same shape as the pin 55 illustrated in FIG. 4. At the time of coupling the connector illustrated in FIG. 5 to the connector illustrated in FIG. 3, the connector case 61 and the connector case 42 are mated with each other, and the four pins 63 to 66 illustrated in FIG. 5 are mated to the four respectively corresponding pins 43 to 46 in FIG. 3. Thus, the electrical connection between the connectors is established, and the circuit board is mounted and fixed to the back wiring board 23.

Note that, as illustrated in FIG. 3, the first power supply pin 44 and the second power supply pin 45 may have lengths shorter than the frame ground pin 43 and the signal ground pin 46. In other words, focusing on the end locations of portions of the pins 43 to 46 where the pins 43 to 46 are mated with other pins, that is, the end locations of the mating portions 52 and 53 in FIG. 4, the ends of the ground pins 43 and 46 protrude further than the ends of the power supply pins 44 and 45. For the opposite pins 63 to 66 to be mated with the pins 43 to 46, as illustrated in FIG. 5, the end locations of the pins 63 to 66 align (arranged at the same position in the direction of insertion at the time of mating). Accordingly, when the connector of FIG. 3 and the connector of FIG. 5 are brought closer to each other and coupled to each other, the ground pins 43 to 46 and the pins 63 to 66 are in contact with each other and electrically connected first, and then the power supply pins 44 and 45 and the pins 64 and 65 are in contact with each other and electrically connected. That is, the connection of the ground is established first, and then the connection of the power supply is performed, and thus safe power supply connection may be achieved.

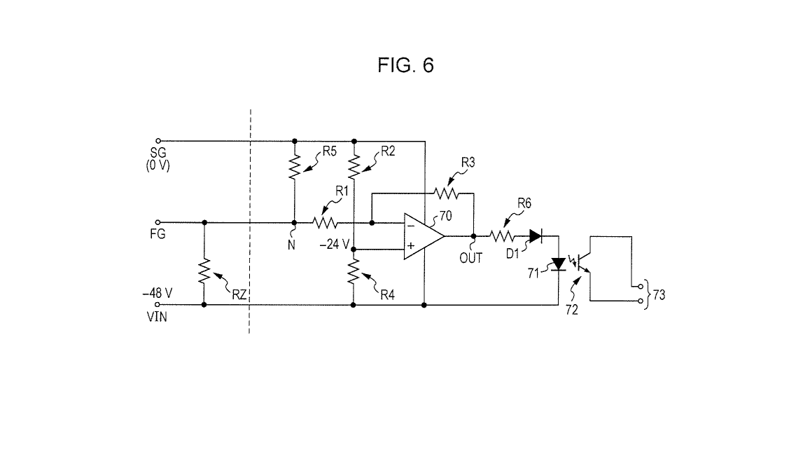

FIG. 6 illustrates an example configuration of an electrical leakage detection circuit. The electrical leakage detection circuit illustrated in FIG. 6 includes an operational amplifier 70, resistive elements R1 to R6, a diode D1, a light-emitting element 71, and a light-receiving element 72. A signal ground SG is connected to the signal ground pin 46 of FIG. 3, a frame ground FG is connected to the frame ground pin 43 of FIG. 3, and a power supply terminal VIN to which a voltage of −48 V is applied is connected to the second power supply pin 45, for example, of FIG. 3. A resistance RZ is a resistance of a path of an electrical leakage in the case where, dew condensation, dusts, or the like causes the power supply and the frame ground to be coupled to each other, and as a result, the electrical leakage flows. The resistance RZ is infinite under normal conditions and has a finite value under abnormal conditions. In an optically coupled unit made up of the light-emitting element 71 and the light-receiving element 72, information is transferred in the form of the intensity of light from the input side to the output side, and the input side and the output side are not electrically connected (directly connected by using an electric conductor). In such a way, a circuit side on which the operational amplifier 70 is provided and an alert output side are electrically insulated.

A circuit portion made up of the operational amplifier 70 and the resistive elements R1 to R5 detects a potential difference between the potential of the signal ground (SG: common ground) and the potential of the frame ground (FG). The resistances of the resistive element R2, the resistive element R3, and the resistive element R4 may be equal to one another, and the combined resistance of the resistive element R1 and the resistive element R5 connected in series (that is, the sum of the two resistances) may be equal to the resistance of the resistive element R3. That is, assuming that the reference characters of the resistive elements indicate the resistances, the resistances may be R2=R3=R4=R1+R5. R2=R4, the signal ground SG is 0 V, and the power supply VIN is −48 V, and therefore the voltage of a non-inverting input end of the operational amplifier 70 is −24 V. At this point, the voltage of an inverting input end of the operational amplifier 70 is also −24 V because of a virtual short circuit.

Since the resistance RZ is infinite under the normal conditions, no current flows through the resistance RZ. Under the normal conditions, the frame ground FG is in a state relatively isolated from the power supply VIN and the signal ground SG. That is, the relative potential of the frame ground FG is determined depending on the operation of the circuit portion made up of the operational amplifier 70 and the resistive elements R1 to R5. R1+R5=R3, the signal ground SG is 0 V, and the voltage of the inverting input end of the operational amplifier 70 is −24 V, and therefore an output OUT of the operational amplifier 70 is −48 V. Accordingly, under the normal conditions, no current flows through the resistive element R6, the diode D1, and the light-emitting element 71, and the light-emitting element 71 does not emit light. In this case, the light-receiving element 72 is in the off state, that is, in the open state.

Under the abnormal conditions where an electrical leakage occurs because of dew condensation, dusts, or the like, the resistance RZ has a finite value or a value of zero. For example, if a complete short circuit occurs such that the resistance RZ has a value of zero, the frame ground FG is forcibly set to have the same potential as the power supply VIN. That is, the potential of a node N is −48 V relative to the potential of the signal ground SG. At this point, since the voltage of the inverting input end of the operational amplifier 70 is −24 V, assuming that the resistances of R1 and R3 are approximately equal (that is, assuming that the resistance of R5 is very small), for example, the output OUT of the operational amplifier 70 is 0 V. Accordingly, under the abnormal conditions, a current flows through the resistive element R6, the diode D1, and the light-emitting element 71, and the light-emitting element 71 emits light. In this case, the light-receiving element 72 is in the on state, that is, in the short-circuit state.

In such a way, depending on whether the normal conditions occur or the abnormal conditions with an electrical leakage occur, either the open state or the short-circuit state occurs between two terminals of an alert contact output 73. Accordingly, it is possible to output an alert by detecting the state between two terminals of the alert contact output 73, when a short-circuit state occurs between these terminals. The electrical leakage state where an alert is output, that is, the value of the resistance RZ may be adjusted by adjusting the resistance of the resistive element R5. If R5=R1, for example, 2×R3=R1, and therefore the output OUT of the operational amplifier 70 is 24 V if the resistance RZ has a value of zero. That is, in the case where R5=R1, for example, an alert output is more likely to occur than in the case where R5<<R1. In such a way, the larger the resistance of the resistive element R5, the more the alert output is likely to occur. This enables the electrical leakage state (the resistance of the resistor RZ) where an alert output occurs to be set by appropriately adjusting the resistance of the resistive element R5. That is, the electrical leakage detection circuit may be designed so as to output an alert if the potential difference between the frame ground and the signal ground is equal to or larger than a predetermined value. Additionally, the design may be made such that the electrical leakage detection circuit outputs an alert before the breaker (the breaker 21-1 or 21-2 of FIG. 1) interrupts a current, by adjusting the resistance of the resistive element R5 as appropriate.

Note that the signal ground SG and the frame ground FG are connected through the resistive element R5. Providing the resistive element R5 enables the potential of the frame ground FG to be relatively changed with respect to the potential of the signal ground SG in the case where a leakage current flows between the frame ground FG and the power supply VIN compared to the case where an electrical leakage does not exist (the case where the resistance RZ is infinite). The change is detected by the operational amplifier 70.

The electrical leakage detection circuit may be provided on a substrate mounted to the back wiring board 23. That is, as described above, a plurality of circuit boards (substrate cards) may be mounted to the back wiring board 23. The electrical leakage detection circuit illustrated in FIG. 6 may be provided on at least one of a plurality of boards mounted to the back wiring board 23.

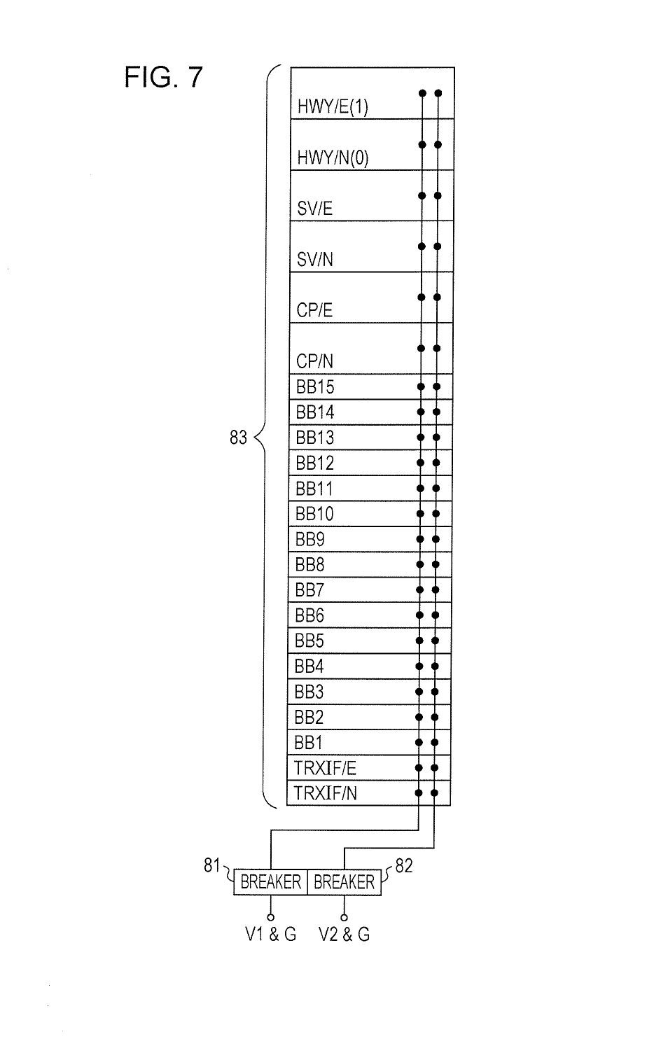

FIG. 7 illustrates an example of a plurality of circuit boards mounted to a back wiring board. In FIG. 7, breakers 81 and 82 correspond to the breakers 21-1 and 21-2 of FIG. 1. A power supply voltage V1 and a ground voltage G from the external DC power supply device 11 illustrated in FIG. 1 are supplied through the breaker 81 to a plurality of circuit boards 83 mounted to the back wiring board 23. Also, a power supply voltage V2 and the ground voltage G from the external DC power supply device 12 illustrated in FIG. 1 are supplied through the breaker 82 to the plurality of circuit boards 83 mounted to the back wiring board 23. In each circuit board 83, portions indicated by two black circles are connection portions made by using a connector between the back wiring board 23 and the circuit board side. By using a connector as illustrated in FIG. 3 to FIG. 5, connection between the back wiring board 23 and each circuit board 83 is made.

HWY is a highway card that performs exchanges with a network, and the circuit boards HWY/E(1) and HWY/N(0) constitute a redundant configuration that supports two-system power supplies. SV is an electrical leakage detection card in which the electrical leakage detection circuit described above is included, and the circuit boards SV/E and SV/N constitute a redundant configuration that supports two-system power supplies. CP is a card in which an arithmetic circuit such as a central processing unit (CPU) is included, and the circuit boards CP/E and CP/N constitute a redundant configuration that supports two-system power supplies. BB1 to BB15 are cards in each of which a baseband circuit is included. TRXIF is a card in which an interface circuit with an amplifier is included, and the circuit boards TRXIF/E and TRXIF/N constitute a redundant configuration that supports two-system power supplies.

The plurality of circuit boards 83 illustrated in FIG. 7 are mounted to the back wiring board 23 through a connector as illustrated in FIG. 3 to FIG. 5. Through the back wiring board 23, the power supply and the signal ground of the external DC power supply device 11, the power supply and the signal ground of the external DC power supply device 12, and the frame ground are provided to each circuit board. At least one of the plurality of circuit boards 83 may be a card in which the electrical leakage detection circuit is included. Note that, in the example of FIG. 7, since two power supply systems are used, two electrical leakage detection circuit cards are provided so as to support the two power supply systems.

While the present disclosure has been described on the basis of the embodiment hereinbefore, the present disclosure is not limited to the above embodiment and may be modified in various forms within the scope indicated by the appended claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A connector comprising:
a first terminal to which a power supply is connected, the power supply being a direct current power supply;
a second terminal to which a signal ground of the direct current power supply is connected; and
a third terminal connected to a frame ground, the third terminal being arranged at a location between the first terminal and the second terminal.

2. The connector according to claim 1, further comprising a fourth terminal to which a power supply is connected, the power supply being a second direct current power supply,
wherein a signal ground of the second direct current power supply is connected to the second terminal such that the first terminal, the second terminal, the third terminal, and the fourth terminal are arranged in an order of the fourth terminal, the first terminal, the third terminal, and the second terminal.

3. An electrical leakage detection device comprising:
a wiring board including
a first terminal to which a power supply is connected, the power supply being a direct current power supply,
a second terminal to which a signal ground of the direct current power supply is connected, and
a third terminal connected to a frame ground, the third terminal being arranged at a location between the first terminal and the second terminal; and
a detection circuit configured to detect a potential difference between a potential of the signal ground and a potential of the frame ground.

4. The electrical leakage detection device according to claim 3, wherein the signal ground and the frame ground are connected through a resistive element.

5. The electrical leakage detection device according to claim 3, wherein the detection circuit is provided on a board mounted to the wiring board, the detection circuit being a circuit connected to the signal ground, the power supply, and the frame ground.

6. The electrical leakage detection device according to claim 3, wherein the detection circuit outputs an alert when the potential difference is equal to or larger than a predetermined value.

7. The electrical leakage detection device according to claim 3, further comprising a breaker configured to interrupt a current in response to an overcurrent of a supply path of the power supply,
wherein the detection circuit outputs an alert before the breaker interrupts a current.

8. The electrical leakage detection device according to claim 3, wherein
the wiring board further includes a fourth terminal to which a power supply is connected, the power supply being a second direct current power supply, and
a signal ground of the second direct current power supply is connected to the second terminal such that the first terminal, the second terminal, the third terminal, and the fourth terminal are arranged in an order of the fourth terminal, the first terminal, the third terminal, and the second terminal.

9. The electrical leakage detection device according to claim 3, wherein
the first terminal, the second terminal, and the third terminal are provided at a mounting location of each of a plurality of boards mounted to the wiring board, and
the detection circuit is provided on at least one of the plurality of boards mounted to the wiring board.
